(19) United States
(12) Patent Application Publication
(10) Pub. No.: US 2007/0070602 A1
(43) Pub. Date: Mar. 29, 2007

(54) Fan unit

(76) Inventor: Cheng-Chang Huang, Taipei (TW)

Correspondence Address: G. LINK Co., LTD, 3550 Bell Road, Minooka, IL, 60447, US

(21) Appl. No.: 11/236,483

(22) Filed: Sep. 28, 2005

(51) Int. Cl. H05K 7/20

(52) U.S. Cl. 361/695

(57) ABSTRACT

A fan unit includes at least a frame member and at least a fan wheel. The frame member is passed through with a flow passage and the flow passage has a first through hole and a second through hole respectively at two lateral sides of the frame member with being penetrated with fixing holes. A first frame wall is disposed inclining and outward diverges radially from the first through hole and a second frame wall inclines toward a direction opposite the first frame wall in the frame member. The fan wheel is disposed in the frame member and has a hub with at least a fan blade extending outward from the periphery of the hub. The first frame wall outward diverges a distance at least exceeding the fixing holes and a non-inclining third frame wall is disposed between the first and second frame walls.

### BACKGROUND OF THE INVENTION

1. Field of the Invention

The present invention is related to a fan unit and particularly to a fan capable of increasing intake fluid.

2. Brief Description of the Related Art

Along with technology and manufacturing process of semi-conductor rapidly progress, work time pulses of electronic components and chips upgrade incessantly. For an ordinary computer main unit, major heat comes from the microprocessor, north bridge and south bridge chips, high performance chip on the VGA card, hard disk, optical drive and power supply. Especially, the microprocessor generates much of the heat and the heat issued from microprocessor with higher frequency issues is closed to 100 watts. The heat nearly 100 watts is equivalent to a piece of hot metal sheet. The surprisingly heat can be imaged that the situation will be worse in the coming days with technology development keeping in a state of change in a fast speed. Due to space limitation, the currently used personal computer and the laptop computer mostly utilize a small sized fan mounted to cooling fins to attach to the heat generation source for achieving effect of heat dissipation. How to promote heat dissipation for the system being operated in fast speed and better effect is a common subject investigated by industry and academic institutions. Natural air convection cooling, forced air convention cooling, liquid indirect or direct cooling and phase change cooling are commonly used cooling ways. The forced air cooling is a very popular way for cooling because air is a kind of un-lacked and most popular fluid and it is acquired without cost and power. The fan is used to drive the air to cause forced convection and it is a best device to perform forced convection. Hence, how to change configuration of the currently used fan for enhancing flow rate thereof, forced convection efficiency and heat dissipation effect is an aim of the present invention.

Taiwanese Patent Publication No. 562391 entitled “CASE BASE OF A HEAT DISSIPATION FAN” discloses an annular wall at the base plate with a plurality of posts supporting a seat plate in the area surrounded by the annular wall. The seat plate has a pipe seat for connecting with the stator and the fan wheel. The inner wall surface of the annular wall is inclined to form an angle of non-90° between the inner wall surface of the annular wall and the seat plate.

The base plate is provided with locating holes and the annular wall has through holes corresponding to the locating holes. Further, it can be seen in the drawings thereof that the annular wall is a thin wall.

The preceding prior art has a problem that it is very easy to become failure while the through holes are fabricated during mold releasing, that is, imperfection rate increases largely while making the annular wall. Further, the through holes affect strength of the annular wall too such that the annular wall breaks at the spots of the through holes to shorten life span thereof.

Taiwanese Paten publication No. 566075 entitled “HEAT DISSIPATION DEVICE WITH FAN FRAME THEREOF” discloses a fan wheel and a fan frame structure. The fan frame structure includes a channel for guiding air current to flow toward an opening from another opening. The inner wall of the channel extends outward with respect to axis of either the channel or the heat dissipation device from at least one of the openings to increase either flowing in area or flowing out area of the air current. Hence, the heat dissipation performance can be enhanced greatly under a condition of assembling with other components being without change.

However, the problem of the preceding prior art is in that the inner wall expands outward a distance without exceeding the screw holes such that it results in insufficient area of intake air is obtained due to the inner wall unable to expand to an extent exceeding the screw holes and the heat dissipation effect incapable of being enhanced substantially.

### SUMMARY OF THE INVENTION

In order to solve the preceding problems, an object of the present invention is to provide a fan unit in which the fan frame thereof provides a first frame wall diverging outward a distance exceeding outer diameter of the frame for increasing flow area of the first through hole thereof.

Another object of the present invention is to provide a fan unit in which the fan wheel can be increased the size thereof to accommodate the outward expanded first frame wall of the fan frame for increasing flow rate and promoting heat dissipation efficiency.

A further object of the present invention is to provide a fan unit in which the first frame wall of the fan frame is inclined to attenuate noise resulted from the fan wheel and the frame wall.

A further object of the present invention is to provide a fan unit in which the second frame wall of fan frame is inclined to expand flow out area of the fluid.

A further object of the present invention is to provide a fan unit in which the third frame wall of fan frame is non-inclined to create pressurization with the fan wheel for increasing flow velocity of the fluid.

Accordingly, a fan unit according to the present invention includes at least a frame member and at least a fan wheel. The frame member is passed through with a flow passage and the flow passage has a first through hole and a second through hole respectively at two lateral sides of the frame member with being penetrated with fixing holes. A first frame wall is disposed inclining and outward diverges radially from the first through hole and a second frame wall inclines toward a direction opposite the first frame wall in the frame member. The fan wheel is disposed in the frame member and has a hub with at least a fan blade extending outward from the periphery of the hub. The first frame wall outward diverges a distance at least exceeding the fixing holes and a non-inclining third frame wall is disposed between the first and second frame walls.

### BRIEF DESCRIPTION OF THE DRAWINGS

The detail structure, the applied principle, the function and the effectiveness of the present invention can be more fully understood with reference to the following description and accompanying drawings, in which:

FIG. 1 is an exploded perspective view of a preferred embodiment of a fan unit according to the present invention;

FIG. 2 is an assembled perspective view of the fan unit shown in FIG. 1;

FIG. 3 is a perspective view illustrating reversed side of the fan unit shown in FIG. 2;

FIG. 4 is a sectional view along line 4-4 shown in FIG. 2;

FIG. 5 is a diagram illustrating enlarged view of the part of dash circle shown in FIG. 4;

FIG. 6 is a sectional view illustrating another configuration of the frame wall of the fan unit in the preferred embodiment thereof; and

FIG. 7 is a diagram illustrating enlarged view of the part of dash circle shown in FIG. 6.

### DETAILED DESCRIPTION OF THE INVENTION

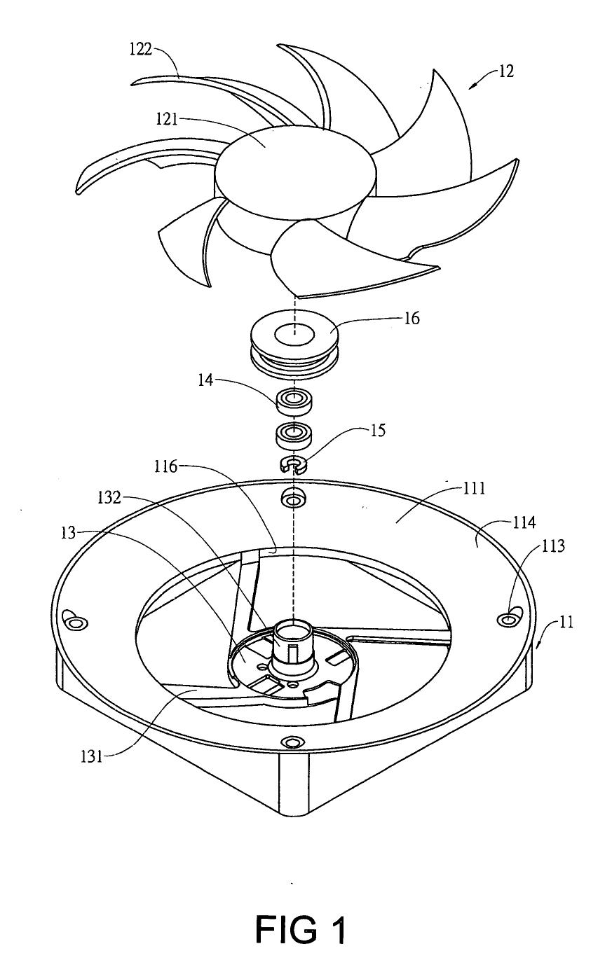

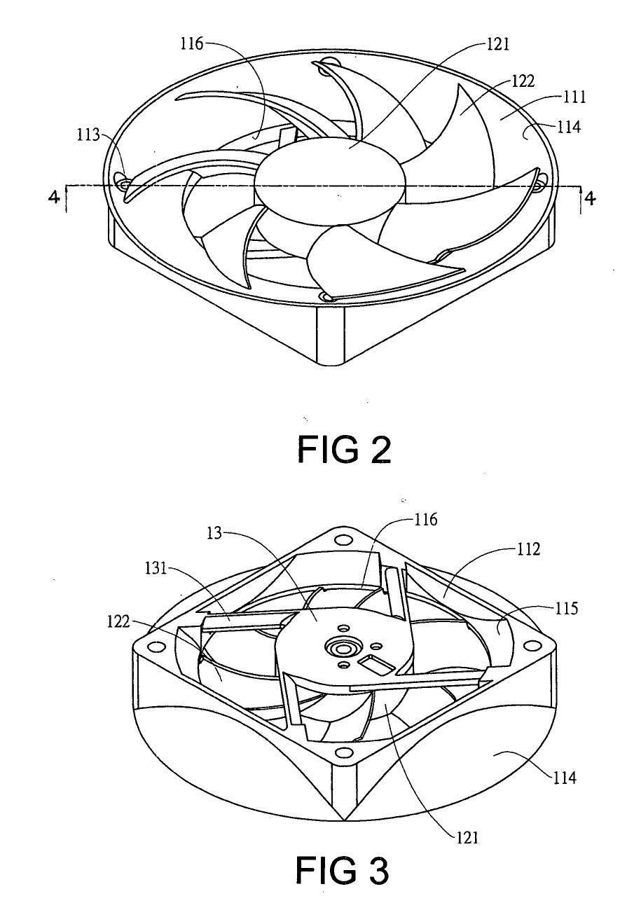

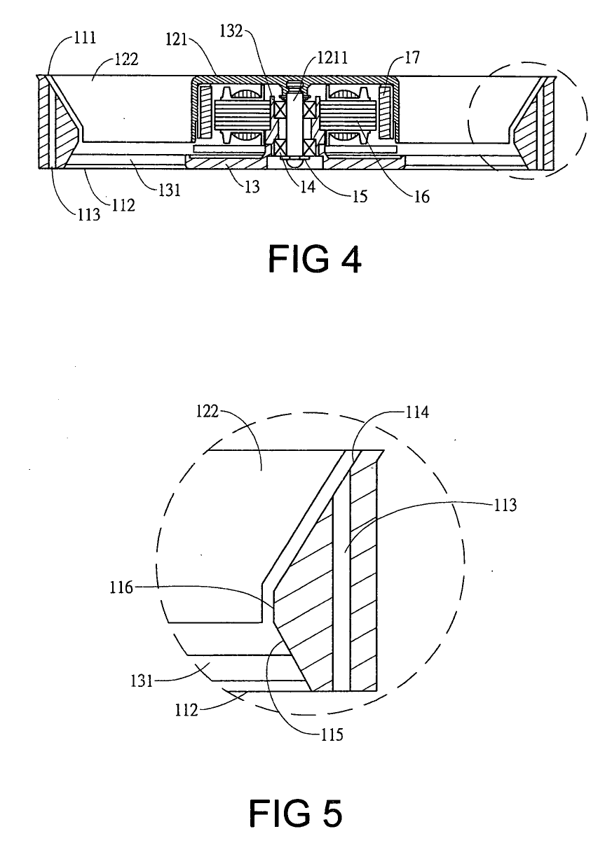

Referring to FIGS. 1 to 4, a preferred embodiment of a fan unit according to the present invention includes a frame member 11 and a fan wheel 12. The frame member 11 provides a flow passage penetrating the frame member 11 and the flow passage forms a first through hole 111 and a second through hole 112 at two lateral sides of the frame member 11 respectively. The frame member 11 has fixing holes 113 for being passed through with fastening parts. A first frame wall 114 extends from the first through hole 111 in the frame member 11 inclining inward and expanding outward radially a distance at least exceeding the fixing holes and a second frame wall 115 extends from the second through hole 112 inclining toward a direction opposite the first frame wall 114. Further, a non-inclining third frame wall 116 is disposed between the first frame wall 114 and the second frame wall 115. Further, a hub seat 13 is disposed next to the second through hole 112 with at least a support element 131 at the periphery of the hub seat 13 being connected to the second frame wall 115. The hub seat 13 provides an axial hollow barrel 132 with at least a bearing 14 and a retaining ring 15 inside. The outer surface of the axial barrel 132 fits with the stator 16 of a motor. The fan wheel 12 has a hub 121 and at least a fan blade 122 extending outward from the periphery thereof and a shaft 1211 with a rotor 17 of the motor is received in the hub 121 as shown in FIG. 4. When the fan unit is assembled, the shaft 1211 penetrates the bearing 14 in the axial barrel 132 with the retaining ring 15 engaging with the shaft 1211 and the fan wheel 12 is movably joined to the hub 13 in the frame member 11 to allow the stator 16 magnetically connecting with the rotor 17.

The fixing holes 113 pass through the first frame wall 114. The first frame wall 114 provides a length thereof different from the second frame wall 115. The dimension of the fan wheel 12 can be increased to comply with outward expansion of the first frame wall 114.

Referring to FIGS. 4 and 5 accompanying with FIG. 1, when magnetization occurs between the stator 16 and rotor 17 and kinetic energy is transferred via physical change, fluid is induced to enter via the first through hole 111 and flow area of the fluid increases due to the first frame wall 114 extending outward radially a distance at least exceeding the fixing holes, that is, the fluid enters via the first through hole 111 increases. When passing through the third frame wall 116, the fluid is pressurized by the fan blade 122 and the third frame wall 116 to speed up the fluid flow. Due to the second frame wall 115 being inclined, the fluid flows divergently after passing through the second frame wall 115 so as to increase movable cooling area. Further, the first frame wall 114 is inclined so that it is capable of greatly attenuating noise created by direct impact with the fluid and noise created by turbulence resulting from non-uniform intake area. In addition, the fixing holes 113 penetrate the first frame wall 114 directly and it promotes perfection rate thereof and overcomes problem of weakness at the part of the fixing holes because of the fixing holes being provided at a thin wall thickness done in the conventional fan.

The first frame wall 114, the second frame wall 115 and the third frame wall 116 in the frame member 11 produce three-stage functions, 1^{st}, increasing intake flow rate of the fluid, 2^{nd}, increasing flow velocity of the fluid, and 3^{rd}, expanding cooling area of the fluid. Hence, heat dissipation efficiency is promoted greatly to overcome another problem of easily creating noise because of too small fluid inlet and insufficient effect of heat dissipation resided in the conventional fan.

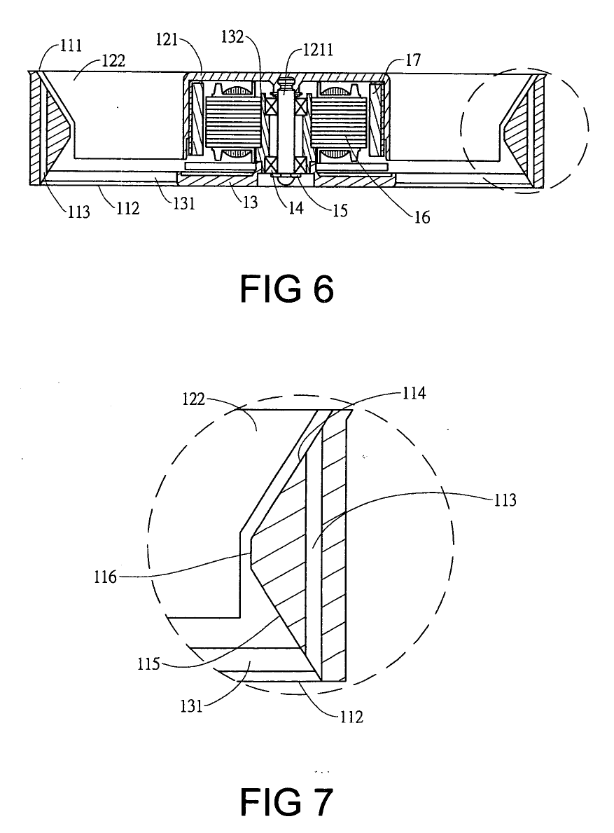

Furthermore, referring to FIGS. 6 and 7, the first frame wall 114 can be provided with the length thereof equal to the second frame wall 115 to constitute a structure of upper-lower symmetry to perform the preceding functions as well.

While the invention has been described with referencing to preferred embodiments thereof, it is to be understood that modifications or variations may be easily made without departing from the spirit of this invention, which is defined by the appended claims.

What is claimed is:

1. A fan unit, comprising:
at least a frame member, being passed through with a flow passage, the flow passage having a first through hole and a second through hole respectively at two lateral sides thereof, being penetrated with fixing holes, having a first frame wall inclining and outward diverging radially from the first through hole and a second frame wall inclining toward a direction opposite the first frame wall; and
at least a fan wheel, being disposed in the frame member, having a hub and at least a fan blade extending outward from the periphery of the hub;
characterized in that the first frame wall outward diverging a distance at least exceeding the fixing holes and a non-inclining third frame wall is disposed between the first and second frame walls.

2. The fan unit as defined in claim 1, wherein the fixing holes penetrate the first frame wall.

3. The fan unit as defined in claim 1, wherein the first frame wall has a length unequal to the second frame wall.

4. The fan unit as defined in claim 1, wherein the first frame wall has a length equal to the second frame wall.
